(19) United States
(12) Patent Application Publication
(10) Pub. No.: US 2012/0000506 A1
(43) Pub. Date: Jan. 5, 2012

(54) PHOTOVOLTAIC MODULE AND METHOD OF MANUFACTURING THE SAME

(75) Inventors: Yuk-Hyun NAM, Goyang-si (KR); Dong-Jin KIM, Seoul (KR); Jung-Eun LEE, Goyang-si (KR); Ku-Hyun KANG, Suwon-si (KR)

(73) Assignees: SAMSUNG SDI CO., LTD.,, Yongin-si (KR); SAMSUNG ELECTRONICS CO., LTD.,, Suwon-si (KR)

(21) Appl. No.: 13/174,908

(22) Filed: Jul. 1, 2011

(30) Foreign Application Priority Data
Jul. 2, 2010 (KR) 10-2010-0063956

(51) Int. Cl. H01L 31/05; H01L 31/0224

(52) U.S. Cl. 136/244; 438/73; 438/98; 257/E31.124

(57) ABSTRACT

A photovoltaic module includes a plurality of solar cells, and a plurality of solar cell separation regions separating adjacent solar cells. Each of the solar cells includes a first electrode layer on a transparent substrate and electrically separated from the first electrode layer of an adjacent solar cell, a second electrode layer over the first electrode layer and electrically separated from the second electrode layer of the adjacent solar cell, first and second electrical and optical photovoltaic layers between the first and second electrode layers, and a conductive interlayer between the first and second photovoltaic layers. At least one of the solar cell separation regions includes a first separation groove which extends through the first electrode layer; and a second separation groove which extends through the first photovoltaic layer which fills the first separation groove, and the interlayer.

This application claims priority to Korean Patent Application Serial No. 10-2010-0063956 filed on Jul. 2, 2010, and all the benefits accruing therefrom under 35 U.S.C. §119(a), the entire disclosure of which is hereby incorporated by reference.

### BACKGROUND OF THE INVENTION

(1) Field of the Invention

The invention relates generally to a photovoltaic module and a method of manufacturing the same, and more particularly, to a separation structure for separating solar cells and a method of manufacturing the same

(2) Description of the Related Art

Solar cells or photovoltaic cells are basic elements of a solar generator that directly converts sunlight into electricity. Semiconductor p-n junctions constituting solar cells may be used for photovoltaic layers. The solar cells having the p-n junctions are based on the principle in which when solar light having energy greater than band-gap energy Eg of a semiconductor is incident on the solar cells, electron-hole pairs are generated in the solar cells. Thus, solar cells having p-n junctions generate electron-hole pairs by the solar light, and due to an electric field generated in a p-n junction portion, electrons of the electron-hole pairs move to an n-layer while holes thereof move to a p-layer, so a flow of a current occurs, thereby converting the solar light into electric energy.

Commonly, a photovoltaic module is made by a cascade connection of a plurality of solar cells.

Referring to FIG. 1, in order to improve efficiency of solar cells in the conventional photovoltaic module, each of the recent solar cells uses a structure in which a plurality of photovoltaic layers are cascade-connected, and which has a conductive interlayer 310 interposed between first and second photovoltaic layers 210 and 410, which have different band gaps and are electrical and optical layers. The cascade-connected photovoltaic layers are between first and second electrode layers 110 and 510, which are formed on or over a transparent substrate 100. In order to form the photovoltaic module, separation regions such as first, second, third and fourth separation regions P1, P2, P3 and P4 are required for a cascade connection between two solar cells. The first separation region P1 is a region for separating the first electrode layer 110, the second separation region P2 is a region for separating the conductive interlayer 310, the third separation region P3 is a region for electrically connecting the first and second electrode layers 110 and 510 to each other, and the fourth separation region P4 is a region for separating solar cells from each other.

Commonly, for the convenience of the process, laser etching is used for patterning the separation regions P1 to P4. Unlike the etching technologies using chemical reaction, such as dry etching and wet etching, the laser etching is achieved by sublimation or vaporization caused by use of high energy such as laser beams. When the laser etching is used for the separation, conductive residues occurring due to the sublimation or vaporization of conductive materials may contaminate sidewalls existing in the separation regions. The contamination by the conductive materials, made on the separation sidewalls, may cause a leakage current between the first electrode layer 110 and the interlayer 310, or between the interlayer 310 and the first and second electrode layers 110 and 510, thereby reducing efficiency of the photovoltaic module.

For example, when the second separation region P2 is formed by patterning or etching the interlayer 310 and the first photovoltaic layer 210, conductive residues created by sublimation or vaporization of conductive materials of the first electrode layer 110 may electrically leakably connect the first electrode layer 110 and the interlayer 310, thereby causing a leakage current. In addition, when the fourth separation region P4 for separating adjacent solar cells is formed, conductive residues created by sublimation or vaporization of conductive materials of the first electrode layer 110 may electrically leakably connect the first electrode layer 110 and the interlayer 310, or the interlayer 310 and the second electrode layer 510, thereby causing a leakage current and thus reducing efficiency of the photovoltaic module. Therefore, it is required to prevent the leakage current caused by the laser etching.

Also, when the third separation region P3 is formed by laser etching to electrically connect the first electrode layer 110 and the second electrode layer 510, conductive residues generated by sublimation or vaporization of conductive materials of the first electrode layer 110 or the interlayer 310 are attached onto separation sidewalls, and a lifting-off phenomenon occurs in which conductive materials or plug materials for electrically connecting the first electrode layer 110 and the second electrode layer 510 are partially lifted off. Therefore, it is required to prevent electrical disconnection caused by the lifting-off phenomenon.

### BRIEF SUMMARY OF THE INVENTION

Accordingly, an exemplary embodiment of the invention provides a photovoltaic module structured to reduce a leakage current which may occur when separation regions are formed by laser etching.

Another exemplary embodiment of the invention provides a method for separating solar cells in a photovoltaic module so as to reduce a leakage current which may occur when separation regions are formed by laser etching.

Another exemplary embodiment of the invention provides a photovoltaic module structured to reduce lifting off of plug materials, which may occur when separation regions are formed by laser etching.

Another exemplary embodiment of the invention provides a method for separating solar cells in a photovoltaic module so as to reduce lifting off of plug materials, which may occur when separation regions are formed by laser etching.

In accordance with one exemplary embodiment of the invention, there is provided a photovoltaic module including a plurality of solar cells, and a plurality of solar cell separation regions separating the solar cells.

Each of the solar cells includes a first electrode layer on a transparent substrate and electrically separated from the first electrode layer of an adjacent solar cell, a second electrode layer over the first electrode layer and electrically separated from second electrode layer of the adjacent solar cell, first and second electrical and optical photovoltaic layers between the first and second electrode layers, and a conductive interlayer between the first and second photovoltaic layers. At least one of the solar cell separation regions includes a first separation groove which extends through the first electrode layer, and a second separation groove which extends through the first photovoltaic layer which fills the first separation groove, and the interlayer. In an exemplary embodiment, the second photovoltaic layer may be filled in the second separation groove.

In an exemplary embodiment, portions of the first photovoltaic layer may exist between sidewalls of the first electrode layer at the first separation groove, and sidewalls of the second photovoltaic layer in the second separation groove.

In accordance with another exemplary embodiment of the invention, there is provided a photovoltaic module including a plurality of solar cells, and a plurality of solar cell separation regions separating first and second solar cells adjacent to each other. Each of the solar cells includes a first electrode layer on a transparent substrate, a second electrode layer over the first electrode layer, first and second photovoltaic layers between the first and second electrode layers, and an electrically conductive interlayer between the first and second photovoltaic layers. At least one of the solar cell separation regions includes a first separation groove which separates the first electrode layer, a second separation groove which separates the second electrode layer, a conductive plug which electrically connects the separated second electrode layer of the first solar cell to the separated first electrode layer of the adjacent second solar cell, and a third separation groove which has a width greater than that of the second separation groove. The second photovoltaic layer over the separated first electrode layer may be separated by the second separation groove. The first photovoltaic layer and the interlayer over the separated first electrode layer may be separated by the third separation groove. Portions of the separated second photovoltaic layer may be between sidewalls of the third separation grooves and sidewalls of the second separation groove.

In accordance with another exemplary embodiment of the invention, there is provided a photovoltaic module including a plurality of solar cells, adjacent cells of which are electrically cascade-connected, and a plurality of solar cell separation regions separating the adjacent solar cells. Each of the solar cells includes a first electrode layer on a transparent substrate, a first photovoltaic layer on the first electrode layer, a conductive interlayer on the first photovoltaic layer, a second photovoltaic layer including first and second layers, on the conductive interlayer, and a second electrode layer on the second layer. At least one of the solar cell separation regions may include a first separation groove which extends from a surface of the first electrode layer, and through the first layer, the interlayer, and the first photovoltaic layer.

In accordance with yet another exemplary embodiment of the invention, there is provided a method for separating solar cells, including forming a first electrode layer on a transparent layer, forming first and second separation grooves which separate the first electrode layer, forming a first photovoltaic layer on the first electrode layer and filling the first and second separation grooves, forming a conductive interlayer on the first photovoltaic layer, and forming a third separation groove which separates the conductive interlayer and the first photovoltaic layer filled in the second separation groove.

In accordance with still another exemplary embodiment of the invention, there is provided a method for separating solar cells, including forming a first electrode layer on a transparent substrate, forming a first separation groove which separates the first electrode layer, forming a first photovoltaic layer filling the first separation groove, on the first electrode layer, forming a conductive interlayer on the first photovoltaic layer, forming a first layer of a second photovoltaic layer, on the conductive interlayer, forming second and third separation grooves which separate the first photovoltaic layer, the conductive interlayer, and the first layer, forming on the first layer a second layer as a remainder of the second photovoltaic layer and filling the second and third separation grooves, forming between the second and third separation grooves a fourth separation groove which separates the second photovoltaic layer including the first and second layers, the conductive interlayer, and the first photovoltaic layer, forming a second electrode layer filling the fourth separation groove, on the second layer, and forming a fifth separation groove which separates the second layer filling the third separation groove and the second electrode layer.

### BRIEF DESCRIPTION OF THE DRAWINGS

The above and other features of certain exemplary embodiments of the invention will be more apparent from the following description taken in conjunction with the accompanying drawings, in which:

FIG. 1 is a cross-sectional view of a photovoltaic module according to the prior art;

FIG. 2 is an exemplary embodiment of a plan view of a photovoltaic module according to the invention;

FIG. 3 is an enlarged cross section taken along line III-III′ on the photovoltaic module shown in FIG. 2;

FIGS. 4A to 4F are cross sections illustrating exemplary embodiments of intermediate steps of manufacturing the photovoltaic module shown in FIG. 2;

FIG. 5 is a cross section of another exemplary embodiment of a photovoltaic module according to the invention;

FIGS. 6A to 6G are cross sections illustrating exemplary embodiments of intermediate steps of manufacturing the photovoltaic module shown in FIG. 5;

FIG. 7 is a cross-sectional view of another exemplary embodiment of a photovoltaic module according to the invention;

FIGS. 8A to 8G are cross sections illustrating exemplary embodiments of intermediate steps of manufacturing the photovoltaic module shown in FIG. 7;

FIG. 9 is a cross-sectional view of another exemplary embodiment of a photovoltaic module according to the invention; and

FIGS. 10A to 10G are cross sections illustrating exemplary embodiments of intermediate steps of manufacturing the photovoltaic module shown in FIG. 9.

### DETAILED DESCRIPTION OF THE INVENTION

Exemplary embodiments of the invention will now be described in detail with reference to the accompanying drawings. Although various figures such as thicknesses and sizes are given as an example in embodiments of the invention, it should be noted that the invention is not limited to the details described and illustrated herein. Throughout the drawings and specifications, the same drawing reference numerals will be understood to refer to the same elements, features and structures.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, “connected” includes physically and/or electrically connected. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “over,” “under,” “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “under” relative to other elements or features would then be oriented “over” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

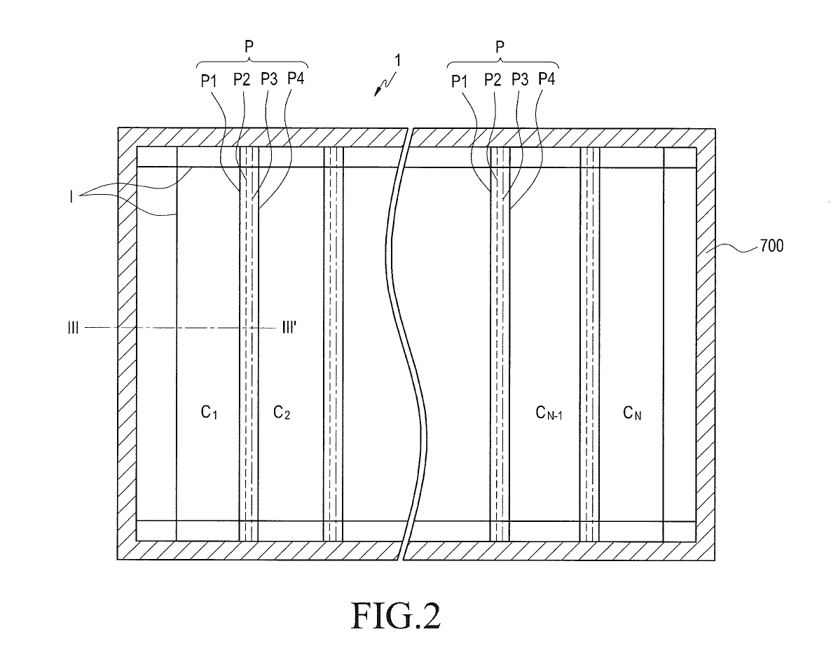

FIG. 2 is a schematic plan view of an exemplary embodiment of a photovoltaic module 1 according to the invention.

Referring to FIG. 2, the photovoltaic module 1 includes a frame 700, a plurality of solar cells C₁, C₂, . . . , C_{N-1}, and C_{N}, and a plurality of cell separation regions P interposed between the cells which separate adjacent cells. In outer regions of the solar cells C₁, C₂, . . . , C_{N-1}, and C_{N}, surrounding separation grooves I extend in horizontal and vertical directions. Edges of the solar cells C₁, C₂, . . . , C_{N-1}, and C_{N} are surrounded by a frame 700.

The solar cells C₁, C₂, . . . , C_{N-1}, and C_{N} longitudinally extend parallel to each other in a vertical direction of the plan view. Adjacent solar cells are separated by the cell separation region P. Each cell separation region P includes first, second, third and fourth separation regions P1, P2, P3, and P4 longitudinally extending parallel to associated solar cells C₁, C₂, . . . , C_{N-1}, and C_{N}.

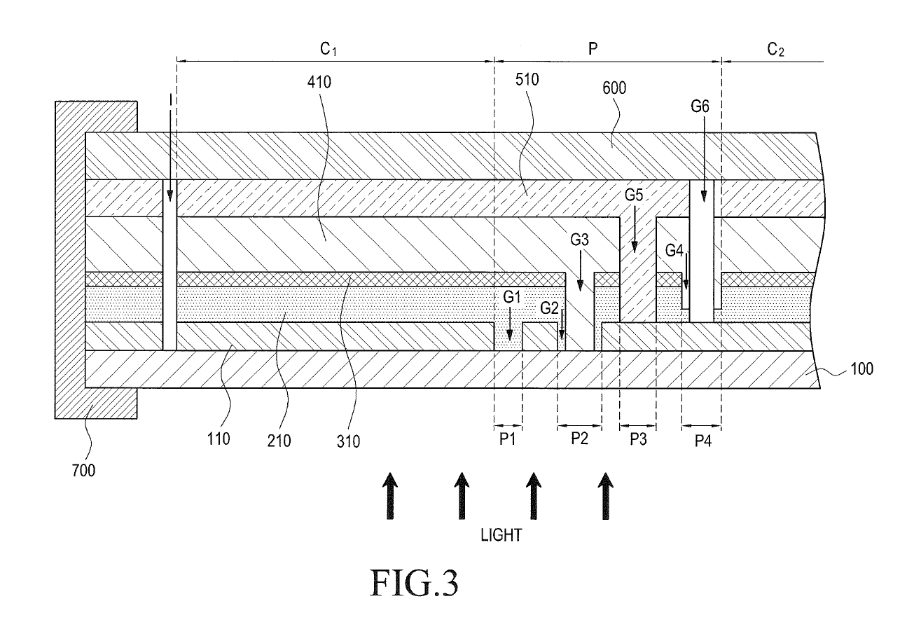

FIG. 3 is an enlarged cross section taken along line III-III′ on the photovoltaic module 1 shown in FIG. 2 according to the invention. A detailed description thereof will be made with reference to FIG. 3.

Referring to FIG. 3, the photovoltaic module 1 further includes a substrate 100, a first electrode layer 110, a first photovoltaic layer 210, an interlayer 310, a second photovoltaic layer 410, a second electrode layer 510 and a protection layer 600. In the cell separation region P between the solar cells C1 and C2, first, second, third, fourth, fifth and sixth separation grooves G1, G2, G3, G4, G5, and G6 correspond to associated separation regions P1, P2, P3, and P4. The protection layer 600 which protects the photovoltaic module 1 from the external shocks and moisture may be on the second electrode layer 510. The frame 700 surrounds the edges of the substrate 100, the first electrode layer 110, the first photovoltaic layer 210, the interlayer 310, the second photovoltaic layer 410, the second electrode layer 510 and the protection layer 600 of the photovoltaic module 1.

The substrate 100 is the base of solar cells, and the substrate 100 may include transparent materials such as a transparent insulating glass and a flexible plastic.

The substrate 100 has front and rear surfaces, and on the front surface is the first electrode layer 110 including an electrical conductor. The first electrode layer 110 may include a transparent and conductive material because the solar light (shown by the upward arrows ‘LIGHT’) is incident on the solar cells through the first electrode layer 110, which serves to flow charges generated in the solar cells. This transparent and conductive material may be selected from the group consisting of, for example, tin oxide (SnO₂), zinc oxide (ZnO), indium tin oxide (“ITO”), indium zinc oxide (“IZO”), aluminum-doped zinc oxide (ZnO:Al), and boron-doped zinc oxide (ZnO:B).

In the first electrode layer 110 are the first and second separation grooves G1 and G2 which correspond to the first and second separation regions P1 and P2, respectively. The first electrode layer 110 is electrically separated between the adjacent solar cells C1 and C2 by the first separation groove G1. The second separation groove G2 is adjacent to the first separation groove G1 and extends parallel thereto. A width between two sidewalls of the first electrode layer 110 at the second separation groove G2 is greater than a width between two sidewalls of the first photovoltaic layer 210 or interlayer 310 at the third separation groove G3. The widths are taken parallel to the front surface of the substrate 100.

In a process of forming the photovoltaic module 1, the first electrode layer 110 is removed by laser etching so that the front surface of the substrate 100 may be exposed at the bottom of the second separation groove G2, and the third separation groove G3 is formed by laser etching so that portions of the first photovoltaic layer 210 including a non-conductive material may remain on the opposing sidewalls of the second separation groove G2, Therefore, when the second separation region P2 which separates the interlayer 310 is formed, the sublimated residues of the first electrode layer 110 creating a leakage current path by being electrically leakably connected to the interlayer 310 may be reduced or effectively prevented.

On the first electrode layer 110 is the first photovoltaic layer 210, which generates electron-hole pairs by absorbing the solar light. The first photovoltaic layer 210 may include, for example, amorphous silicon compounds such as amorphous silicon (Si), amorphous silicon germanium (SiGe) and amorphous silicon carbide (SiC), or II-VI compound semiconductor such as Cu—In—Ga—Se and CdTe. Although not illustrated, the first photovoltaic layer 210 may include a structure in which a first conductive semiconductor layer, an intrinsic semiconductor layer, and a second conductive semiconductor layer are sequentially stacked on the first electrode layer 110. In one exemplary embodiment, for example, a p-type amorphous Si layer, an intrinsic amorphous Si layer, and an n-type amorphous Si layer may be stacked in sequence and collectively form the first photovoltaic layer 210.

The first photovoltaic layer 210 fills the first separation groove G1 in the first electrode layer 110 and contacts the exposed surface of the substrate 100. The first photovoltaic layer 210 also contacts two opposing sidewalls of the first electrode layer 110 in the second separation groove G2 and the exposed portions of the substrate 100, which are adjacent to the sidewalls.

On the first photovoltaic layer 210 is the interlayer 310 including an optically transparent and reflective conductive material. A portion of the light incident on the interlayer 310 is reflected onto the first photovoltaic layer 210, while a remaining portion thereof is transmitted into the second photovoltaic layer 410, thereby increasing optical absorption in the first and second photovoltaic layers 210 and 410, and thus improving efficiency of the solar cells. The interlayer 310 may include zinc oxide (ZnO) or phosphorus-doped silicon oxide (SiOx).

In order to form the second separation region P2 which separates the interlayer 310, the third separation groove G3 extends completely through a thickness of the interlayer 310 and the first photovoltaic layer 210 so that the front surface of the substrate 100 may be exposed. A width of the third separation groove G3 is less than a width of the second separation groove G2. The third separation groove G3 is located within the second separation groove G2 so that portions of the first photovoltaic layer 210 may remain on two sidewalls of the first electrode layer 110 in the second separation groove G2.

The fourth separation groove G4 exists in the fourth separation region P4, and prevents occurrence of a leakage current, which may be caused by the conductive residues generated during manufacturing processes when sublimation or vaporization is performed by laser etching in the fourth separation region P4 which separates adjacent solar cells. A width of the fourth separation groove G4 is greater than a width of the sixth separation groove G6, and the fourth separation groove G4 has a groove shape in which portions of the first photovoltaic layer 210 remain at the bottom of the fourth separation groove G4 and on the first electrode layer 110, while extending completely through a thickness of the interlayer 310.

In a process of forming the photovoltaic module 1, the second photovoltaic layer 410 filled in the fourth separation groove G4 is partially removed by laser etching so that portions of the second photovoltaic layer 410 may remain on two opposing sidewalls of the laser-etched interlayer 310 and first photovoltaic layer 210 in the fourth separation groove G4, thereby forming the sixth separation groove G6. The sixth separation groove G6 extends completely through a thickness of the second electrode layer 510 and the second photovoltaic layer 410, and the remaining portions of the first photovoltaic layer 210, with the first electrode layer 110 exposed at the bottom of the sixth separation groove G6. The remaining portions of the first photovoltaic layer 210 may be about 300 angstroms (Å) to about 1000 Å thick taken in a direction perpendicular to the substrate.

The sixth separation groove G6 whose width is narrower than that of the fourth separation groove G4 may separate the adjacent solar cells. In a process of forming the photovoltaic module 1, when the sixth separation groove G6 is formed by laser etching, sublimation or vaporization of conductive materials of the interlayer 310 may be avoided because portions of the second photovoltaic layer 410 exist on two sidewalls of the interlayer 310, thereby reduce or effectively preventing the possible occurrence of a leakage current caused by the sublimation or vaporization of conductive materials of the interlayer 310.

The second photovoltaic layer 410 is on the interlayer 310, and generates electron-hole pairs by absorbing the solar light. The second photovoltaic layer 410 may include, for example, crystalline silicon such as microcrystalline silicon (mc-Si) and polycrystalline silicon (p-Si), or II-VI compound semiconductor such as Cu—In—Ga—Se and CdTe. Although not illustrated, the second photovoltaic layer 410 may include a structure in which a first conductive semiconductor layer, an intrinsic semiconductor layer, and a second conductive semiconductor layer are sequentially stacked on the interlayer 310. In one exemplary embodiment, for example, a p-type microcrystalline Si layer, an intrinsic microcrystalline Si layer, and an n-type microcrystalline Si layer may be stacked in sequence and collectively form the second photovoltaic layer 410.

In order to form the third separation region P3 which electrically connects the first electrode layer 110 and the second electrode layer 510, the fifth separation groove G5 is extended from the top of the first electrode layer 110, extending completely through a thickness of the second photovoltaic layer 410, the interlayer 310, and the first photovoltaic layer 210. The bottom of the fifth separation groove G5 corresponds to the exposed upper surface of the first electrode layer 110. The fifth separation groove G5 is filled with conductive materials or plug materials of the second electrode layer 510, such that the second electrode layer 510 is electrically connected to the first electrode layer 110.

The second electrode layer 510 located on the second photovoltaic layer 410 may have an optical reflection function, and may include a material selected from the group consisting of molybdenum (Mo), aluminum (Al), and silver (Ag). Therefore, the second electrode layer 510 of the first solar cell C1 is electrically connected to the first electrode layer 110 of the adjacent second solar cell C2 by means of conductive materials or conductive plug materials of the second electrode layer 510 filled in the fifth separation groove G5, thereby making a cascade connection between the adjacent first and second solar cells C1 and C2.

Referring to FIGS. 2 and 3, the surrounding separation grooves I are in outer regions of the photovoltaic module 1, extending completely through the second electrode layer 510, the second photovoltaic layer 410, the interlayer 310, the first photovoltaic layer 210, and the first electrode layer 110. The surrounding separation grooves I extend in horizontal and vertical directions in the plan view. In the outer regions of the photovoltaic module 1, the first electrode layer 110, the first photovoltaic layer 210, the interlayer 310, the second photovoltaic layer 410, and the second electrode layer 510, constituting the solar cells, have non-uniform thicknesses, causing a reduction in efficiency of the solar cells. Therefore, the reduction in the solar cell efficiency may be reduced or effectively prevented by separating the outer regions of the photovoltaic module 1 from the solar cells C₁, C₂, . . . , C_{N-1}, and C_{N} by means of the surrounding separation grooves I.

On the second electrode layer 510 is the protection layer 600, which may protect the solar cells as the protection layer 600 has contamination prevention, external moisture blocking, and heat-resistance features. The protection layer 600 may include a film including glass or a metal layer including, for example, aluminum, and a polymer layer including, for example, polyvinyl fluoride (“PVF”).

The frame 700 combining the substrate 100 with the protection layer 600 is located on edges and sides of layers of the photovoltaic module 1. Specifically, the frame 700 overlaps a lower surface of the substrate 100, outer edges of the substrate 100, the first electrode layer 110, the first photovoltaic layer 210, the interlayer 310, the second photovoltaic layer 410, the second electrode layer 510 and the protection layer 600, and an upper surface of the protection layer 600. The frame 700 serves to block contaminations and moisture which may enter through the sides of layers of the photovoltaic module 1, and to protect the photovoltaic module 1. A protection member (not shown) including acrylic or polyester may be further between the frame 700 and the sides of the layers of the photovoltaic module 1. The frame 700 may include aluminum (Al).

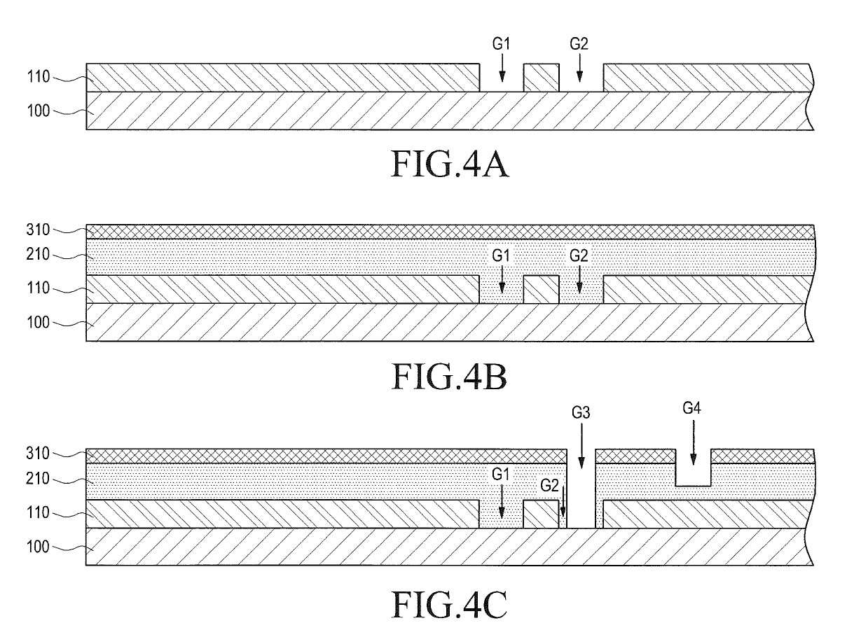

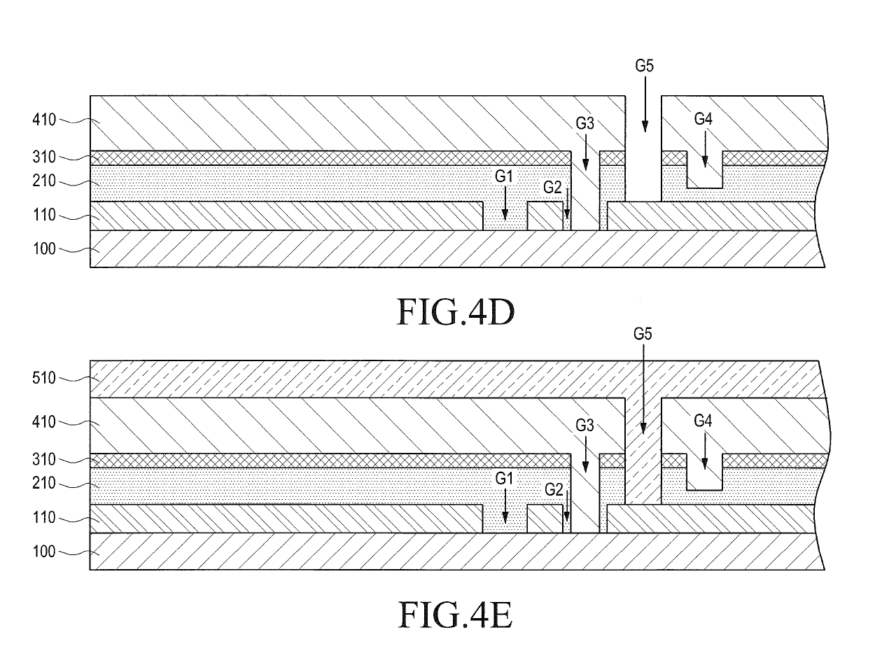

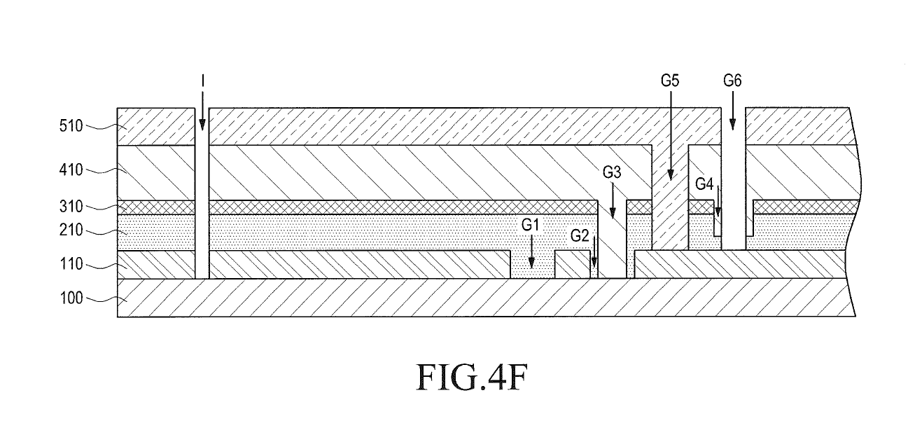

An exemplary embodiment of a method of manufacturing the photovoltaic module 1 shown in FIGS. 2 and 3 will be described in detail below with reference to FIGS. 4A to 4F.

FIGS. 4A to 4F schematically illustrate an exemplary embodiment of a method of manufacturing the photovoltaic module 1 shown in FIGS. 2 and 3.

Referring to FIG. 4A, the first electrode layer 110 is formed on the front surface of the substrate 100 by chemical vapor deposition (“CVD”) or sputtering. The first electrode layer 110 may include a transparent and conductive material selected from the group consisting of, for example, tin oxide (SnO₂), zinc oxide (ZnO), indium tin oxide (“ITO”), indium zinc oxide (IZO), aluminum-doped zinc oxide (ZnO:Al), and boron-doped zinc oxide (ZnO:B). When including ZnO:Al, the first electrode layer 110 may be formed by sputtering, and when including SnO₂, the first electrode layer 110 may be formed by CVD. The first electrode layer 110 may be formed to have a thickness of about 1.0 micrometer (μm) to about 2.0 micrometers (μm).

By patterning or etching the first electrode layer 110, such as by irradiating a laser thereto, first and second separation grooves G1 and G2 are formed in the locations corresponding to the first and second separation regions P1 and P2 in FIG. 3. The laser may be irradiated from the top of the first electrode layer 110 or from the rear surface of the substrate 100. In one exemplary embodiment, for example, the first and second separation grooves G1 and G2 may be formed using an X-Y table and a neodymium-doped yttrium aluminium garnet (Nd:YAG) laser having a wavelength of about 355 nanometers (nm) and a power of about 3 watts (W) to about 6 W. The first separation groove G1 may be about 30 μm to about 200 μm wide, and the second separation groove G2 may be about 50 μm to about 200 μm wide.

Referring to FIG. 4B, the first photovoltaic layer 210 is formed on the first electrode layer 110 and extends to the exposed front surface of the substrate 100, completely filling the first and second separation grooves G1 and G2. The first photovoltaic layer 210 may include, for example, amorphous silicon compounds such as amorphous silicon (a-Si), amorphous silicon germanium (a-SiGe) and amorphous silicon carbide (a-SiC), or II-VI compound semiconductor such as Cu—In—Ga—Se and CdTe. Although not illustrated, the first photovoltaic layer 210 may be formed to have a structure in which a first conductive semiconductor layer, an intrinsic semiconductor layer, and a second conductive semiconductor layer are sequentially stacked on the first electrode layer 110. In one exemplary embodiment, for example, a p-type amorphous Si layer, an intrinsic amorphous Si layer, and an n-type amorphous Si layer may be stacked in sequence. Their thicknesses may be different according to the materials of the first photovoltaic layer 210. For example, by using the CVD, the first photovoltaic layer 210 may include a p-type amorphous Si layer with a thickness of about 50 Å to about 300 Å, an intrinsic amorphous Si layer with a thickness of about 1500 Å to about 3500 Å, and an n-type amorphous Si layer with a thickness of about 100 Å to about 300 Å. On the first photovoltaic layer 210 is formed a conductive interlayer 310, which may include zinc oxide (ZnO) or phosphorus-doped silicon oxide (SiOx). When including zinc oxide (ZnO), the interlayer 310 may be formed by CVD to have a thickness of about 200 Å to about 1000 Å.

Referring to FIG. 4C, third and fourth separation grooves G3 and G4 may be formed by patterning or etching the interlayer 310 and the first photovoltaic layer 210, such as by irradiating a laser thereto. The first electrode layer 110 on the bottom of the third separation groove G3 was already removed when the second separation groove G2 was formed, which makes it possible to prevent residues caused by sublimation or vaporization of the first electrode layer 110 from being electrically connected to the interlayer 310. The third separation groove G3 is located within the second separation groove G2 so that its width may be narrower than that of the second separation groove G2, and is formed to expose the front surface of the substrate 100. Therefore, the third separation groove G3 is formed such that portions of the first photovoltaic layer 210 filling the second separation groove G2 may remain on two opposing sidewalls of the first electrode layer 110 in the second separation groove G2. The third separation groove G3 is about 40 μm to about 190 μm wide, and its width is less than that of the second separation groove G2. In one exemplary embodiment, for example, the third separation groove G3 may be formed using an X-Y table and the second harmonic of the Nd:YAG laser having a wavelength of about 532 nm and a power of about 0.3 W to about 0.5 W.

To form the fourth separation groove G4, laser etching is performed using a laser whose power is lower than that used to form the third separation groove G3 so that portions of the first photovoltaic layer 210 may remain on a front surface of the first electrode layer 110 within the fourth separation groove G4. Thus, when the fourth separation groove G4 is formed, sublimated or vaporized residues of the first electrode layer 110 which are electrically leakably connected to the interlayer 310 may be reduced or effectively prevented. The first photovoltaic layer 210 remaining on the first electrode layer 110 on the bottom of the fourth separation groove G4 may be about 300 Å to about 1000 Åthick. In one exemplary embodiment, for example, the fourth separation groove G4 may be formed using the second harmonic of the Nd:YAG laser having a wavelength of about 532 nm, which is the same as that used to form the third separation groove G3, with a power of about 0.1 W to about 0.16 W. The fourth separation groove G4 may be about 50 μm to about 200 μm wide.

In the alternative, when the third separation groove G3 is formed, a laser may be irradiated onto the rear surface of the substrate 100, e.g., onto the opposite surface of the substrate 100 on which the first photovoltaic layer 210 and the interlayer 310 are formed. When the fourth separation groove G4 is formed, a laser may be irradiated onto the interlayer 310. It will be understood by those skilled in the art that by doing so, the thickness of the first photovoltaic layer 210 remaining on the first electrode layer 110 on the bottom of the fourth separation groove G4 may be easily adjusted.

Referring to FIG. 4D, the second photovoltaic layer 410 is formed on the interlayer 310 and in the third and fourth separation grooves G3 and G4. A fifth separation groove G5 is formed by irradiating a laser onto the second photovoltaic layer 410, or onto the opposite surface of the substrate 100 on which the second photovoltaic layer 410 is formed. The fifth separation groove G5 is formed from the front surface of the first electrode layer 110, extending through the second photovoltaic layer 410, the interlayer 310, and the first photovoltaic layer 210. The fifth separation groove G5 is interposed between the third and fourth separation grooves G3 and G4, and is located to correspond to the third separation region P3 as described above with reference to FIGS. 2 and 3.

The second photovoltaic layer 410 may be formed by CVD. The second photovoltaic layer 410 may include, for example, microcrystalline Si or polycrystalline Si. Although not illustrated, the second photovoltaic layer 410 may be formed to have a structure in which a p-type microcrystalline Si layer, an intrinsic microcrystalline Si layer, and an n-type microcrystalline Si layer are sequentially stacked on the interlayer 310. In one exemplary embodiment, for example, when formed of microcrystalline Si, the second photovoltaic layer 410 may be about 1.5 μm to about 3.0 μm thick.

The fifth separation groove G5 may be about 50 μm to about 100 μm wide, and may be formed using the second harmonic of the Nd:YAG laser having a wavelength of about 532 nm and a power of about 0.3 W to about 0.5 W.

Referring to FIG. 4E, the second electrode layer 510 is formed on the second photovoltaic layer 410 and in the fifth separation groove G5. The second electrode layer 510 having optical reflection characteristics may re-reflect the light having arrived at the second electrode layer 510 onto the first photovoltaic layer 210 or the second photovoltaic layer 410, thereby improving the solar cell efficiency. The second electrode layer 510 is electrically connected to the first electrode layer 110 by extending from the front surface of the first electrode layer 110, and filling the fifth separation groove G5. In one exemplary embodiment, for example, the second electrode layer 510 may include a material selected from the group consisting of aluminum (Al), silver (Ag), and molybdenum (Mo). The second electrode layer 510 may be formed to have a double-layer structure such as ZnO/Ag, ZnO/A1, and ZnO/Mo. In one exemplary embodiment, the second electrode layer 510 has a double-layer structure of ZnO/Ag, ZnO which may be formed by CVD to have a thickness of about 500 Å to about 1500 Å, and Ag may be formed by sputtering to have a thickness of about 1000 Å to about 5000 Å.

Referring to FIG. 4F, a sixth separation groove G6 and a surrounding separation groove I are formed. The sixth separation groove G6 is formed to expose the surface of the first electrode layer 110, extending through the second electrode layer 510, the second photovoltaic layer 410, and the first photovoltaic layer 210 which are on the first electrode layer 110. The sixth separation groove G6 is formed such that the second photovoltaic layer 410 filling the fourth separation groove G4 is partially removed and portions of the second photovoltaic layer 410 may remain on both opposing sidewalls of the interlayer 310 and the first photovoltaic layer 210. The sixth separation groove G6 may be formed using the second harmonic of the Nd:YAG laser having a wavelength of about 532 nm and a power of about 0.3 W to about 0.7 W. The sixth separation groove G6 may have a width of about 40 μm to about 190 μm, which is narrower than that of the fourth separation groove G4.

The surrounding separation groove I may be formed using the second harmonic of the Nd:YAG laser having a wavelength of about 532 nm and a power of about 0.3 W to about 0.7 W. The surrounding separation groove I, as illustrated in FIG. 2, extends along the edges of the photovoltaic module 1 in the horizontal and vertical directions, and is formed from the top of the substrate 100, extending through the second electrode layer 510, the second photovoltaic layer 410, the interlayer 310, the first photovoltaic layer 210, and the first electrode layer 110. Although one surrounding separation groove I is shown in FIGS. 2 and 3, a plurality of surrounding separation grooves may be formed in parallel.

As described above, the first electrode layer 110 is separated by the second separation groove G2, and the third separation groove G3 whose width is narrower than that of the second separation groove G2 is formed such that portions of the first photovoltaic layer 210 may remain on both sidewalls of the separated first electrode layer 110, thereby reducing or effectively preventing the possible leakage current which may occur when the residues of the first electrode layer 110 are electrically leakably connected to the interlayer 310 due to the sublimation or vaporization of conductive materials of the first electrode layer 110. Also, the fourth separation groove G4 is formed such that portions of the first photovoltaic layer 210 remain on the bottom of the fourth separation groove G4, thereby preventing the residues of the first electrode layer 110 from being electrically leakably connected to the interlayer 310 due to the sublimation or vaporization of conductive materials of the first electrode layer 110.

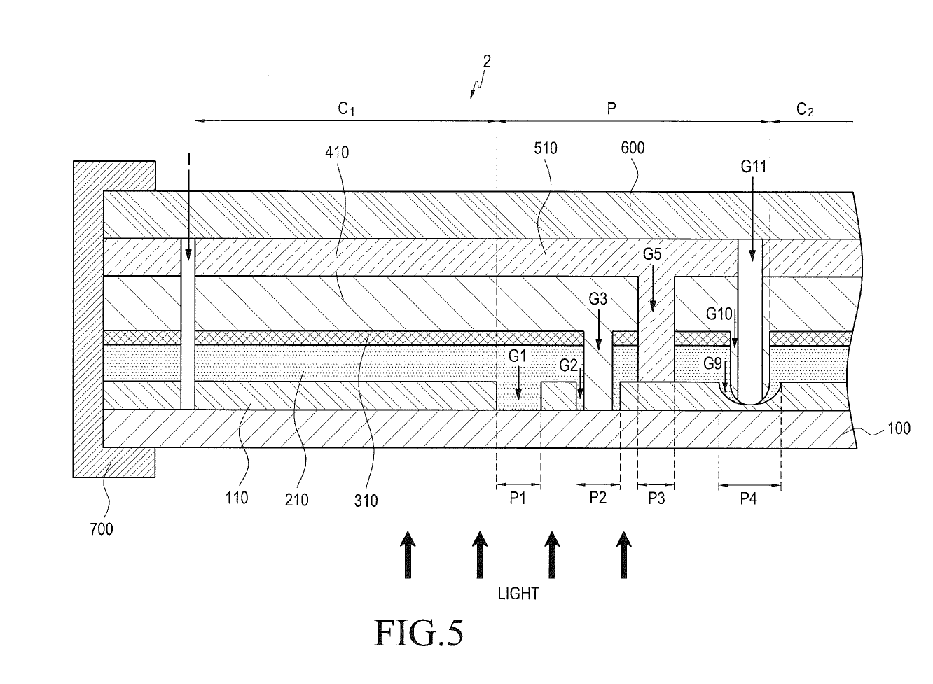

A plan view of a photovoltaic module 2 according to the invention is substantially similar to that illustrated in FIG. 2. FIG. 5 illustrates an enlarged cross section of another exemplary embodiment of a photovoltaic module taken along line III-III′ of FIG. 2 according to the invention. In the photovoltaic module 2 according to the illustrated embodiment, first to third separation regions P1˜P3 except for a fourth separation region P4 are substantially identical in structure to the first to third separation regions P1˜P3 according to the illustrated embodiment described with reference to FIG. 3, so a description thereof will be omitted to avoid duplicate description, and only a structure related to the fourth separation region P4 will be described below.

Referring to FIG. 5, the fourth separation region P4 has ninth to eleventh separation grooves G9, G10, and G11. The ninth separation groove G9 has a bottom which is a concave upper surface of the first electrode layer 110. The bottom of the ninth separation groove G9 has a substantially curved shape like a circular arc in the fourth separation region P4. In other words, portions of the first electrode layer 110 remain on the bottom of the ninth separation groove G9 and between adjacent solar cells C1 and C2, which electrically connect the adjacent solar cells C1 and C2. A thickness of the remaining first electrode layer 110 may be determined taking into account the conductivity of the first electrode layer 110 which electrically connects the adjacent solar cells C1 and C2, and the thickness may be about 2000 Å to about 8000 Å.

The tenth separation groove G10 is narrower than the ninth separation groove G9. In an exemplary embodiment, the tenth separation groove is formed by laser-etching the first photovoltaic layer 210 filled in the ninth separation groove G9 and the interlayer 310 on the photovoltaic layer 210, such that the bottom of the tenth separation groove G10 has a circular arc shape which contacts the circular arc of the ninth separation groove G9. Therefore, portions of the first photovoltaic layer 210 exist between opposing both sidewalls of the circular arcs of the tenth separation groove G10 and the ninth separation groove G9, respectively. Because portions of the first electrode layer 110 are removed by the ninth separation groove G9, sublimation or vaporization of conductive materials of the first electrode layer 110 may be reduced when the tenth separation groove G10 is formed. Therefore, a leakage current may be reduced, which may occur when the sublimated conductive residues of the first electrode layer 110 are electrically leakably connected to the interlayer 310.

The eleventh separation groove G11, which is narrower than the tenth separation groove G10, is located within the tenth separation groove G10, and the bottom of the eleventh separation groove G11 has a substantially circular arc shape which contacts the circular arcs on the bottoms of the ninth and tenth separation grooves G9 and G10. Therefore, where the eleventh separation groove G11 extends through the second electrode layer 510 and the second photovoltaic layer 410, portions of the second photovoltaic layer 410 exist between both sidewalls of the interlayer 310 and the first photovoltaic layer 210 in the eleventh separation groove G11 and the tenth separation groove G10. Thus, when the eleventh separation groove G11 is formed by laser etching, the contamination by residues of conductive materials due to sublimation or vaporization of the interlayer 310 may be reduced or effectively prevented.

By forming the ninth to eleventh separation grooves G9˜G11, separation between adjacent solar cells may be achieved without causing current leakage.

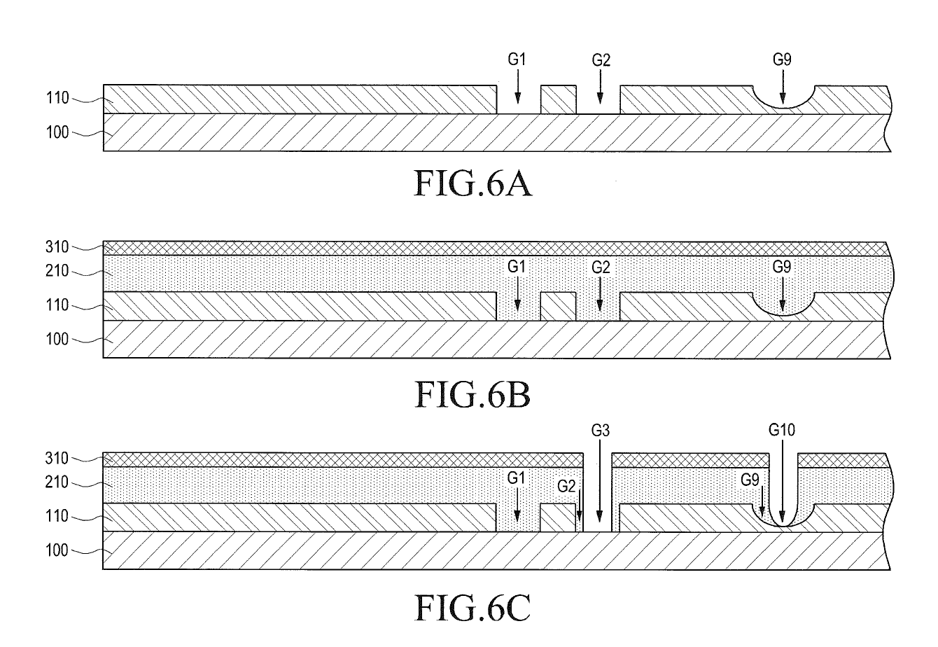

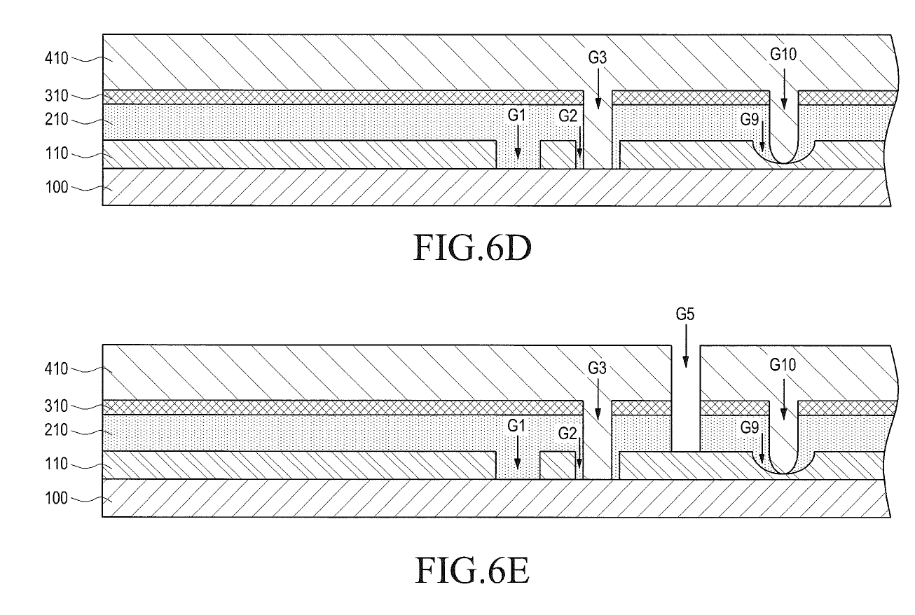

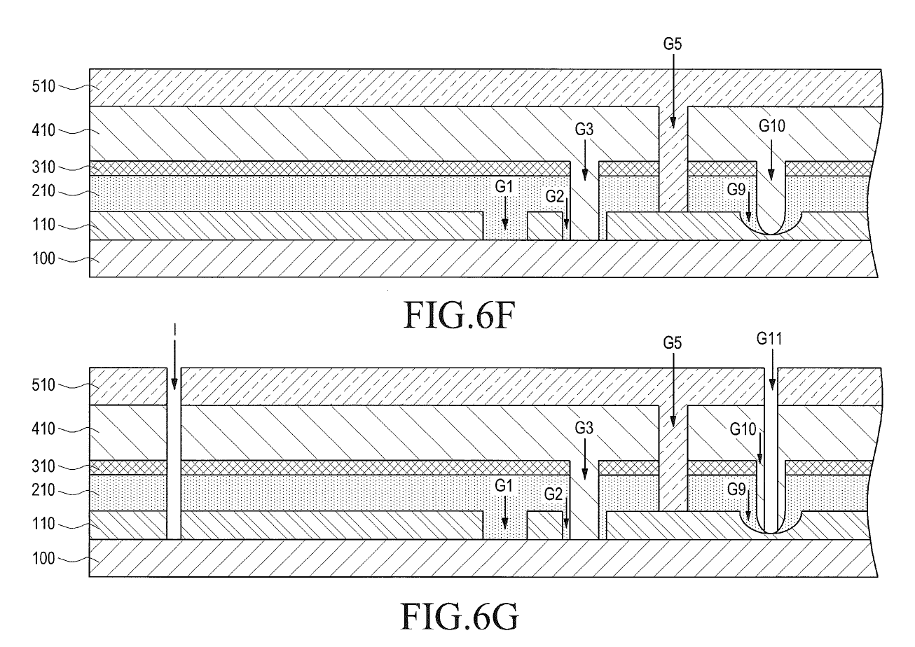

An exemplary embodiment of method of manufacturing the photovoltaic module 2 shown in FIG. 5 will be described in detail below with reference to FIGS. 6A to 6G.

FIGS. 6A to 6G schematically illustrate an exemplary embodiment of a method of manufacturing the photovoltaic module 2 shown in FIG. 5.

Referring to FIG. 6A, the first electrode layer 110 is formed on the substrate 100. Material, thickness and forming method of the first electrode layer 110 may be substantially identical to those described with reference to FIG. 4A. By patterning the first electrode layer 110 by irradiating a laser thereto, the first, second and ninth separation grooves G1, G2, and G9 are formed in the locations corresponding to the first, second and fourth separation regions P1, P2, and P4 in FIG. 2. In one exemplary embodiment, for example, the first and second separation grooves G1 and G2 may be formed by irradiating the Nd:YAG laser having a wavelength of about 1064 nm and a power of about 10 W to about 16 W to the first electrode layer 110, or to the rear surface of the substrate 100 on which the first electrode layer 110 is formed. The first and second separation grooves G1 and G2 may be about 40 μm to about 80 μm wide. The ninth separation groove G9 may be formed by irradiating the Nd:YAG laser having a wavelength of about 1064 nm and a power of about 2 W to about 5 W to the first electrode layer 110. The ninth separation groove G9 may be about 40 μm to 80 μm wide. By adjusting intensity of laser to have Gaussian distribution, such as by adjusting a slit device of a laser generating device, the bottom of the ninth separation groove G9 may be shaped to have a curved shape like a substantially circular arc as shown in FIG. 6A. A portion of the first electrode layer 110 remaining between the bottom of the ninth separation groove G9 and the substrate 100 may be about 2000 Å to about 8000 Å thick taken perpendicular to the substrate 100.

Referring to FIG. 6B, on the first electrode layer 110 is formed the first photovoltaic layer 210, filling the first, second and ninth separation grooves G1, G2 and G9. The first photovoltaic layer 210 is filled in the first and second separation grooves G1 and G2 from the front surface of the substrate 100, but the first photovoltaic layer 210 is filled in the ninth separation groove G9 from the surface of a circular arc or a curved arc of the first electrode layer 110. Material, thickness and forming method of the first photovoltaic layer 210 may be similar to those described with reference to FIG. 4B.

On the first photovoltaic layer 210 is formed the conductive interlayer 310, which may include zinc oxide (ZnO) or phosphorus-doped silicon oxide (SiOx). When including zinc oxide (ZnO), the interlayer 310 may be formed by CVD to have a thickness of about 200 Å to about 1000 Å.

Referring to FIG. 6C, the third and tenth separation grooves G3 and G10 may be formed by etching or patterning the first photovoltaic layer 210 and the interlayer 310 such as by irradiating a laser thereto. The third separation groove G3 is substantially identical in structure to the third separation groove G3 shown in FIG. 4C, but may be different in width. The third separation groove G3 is about 35 μm to 45 μm wide, which is less than the width of the second separation groove G2. In one exemplary embodiment, for example, the third separation groove G3 may be formed using the second harmonic of the Nd:YAG laser having a wavelength of about 532 nm and a power of about 0.3 W to about 0.6 W.

The tenth separation groove G10 is located within the ninth separation groove G9, and its bottom has a shape of a circular arc or curved arc which contacts the surface of the substantially circular arc or curved arc of the first electrode layer 110 at one point or one portion. The tenth separation groove G10 is formed such that portions of the first photovoltaic layer 210 filled in the ninth separation groove G9 may remain on both opposing of the circular arc or curved arc of the first electrode layer 110. The tenth separation groove G10 is about 35 μm to about 45 μm wide, which is less than the width of the ninth separation groove G9. In one exemplary embodiment, for example, the tenth separation groove G10 may be formed using the second harmonic of the Nd:YAG laser having a wavelength of about 532 nm and a power of about 0.3 W to about 0.6 W. Portions of the first electrode layer 110, existing on the bottom of the tenth separation groove G10, are removed in advance when the ninth separation groove G9 is formed, thereby reducing the amount of conductive materials of the first electrode layer 110 which undergo sublimation or vaporization when the tenth separation groove G10 is formed. Thus, occurrence of the leakage current path in which the sublimated or vaporized residues of the first electrode layer 110 are electrically leakably connected to the interlayer 310 may be reduced.

Referring to FIG. 6D, the second photovoltaic layer 410 is formed on the interlayer 310, filling the third and tenth separation forms G3 and G10. Material, thickness and forming method of the second photovoltaic layer 410 may be similar to those described with reference to FIG. 4D.

Referring to FIG. 6E, the fifth separation groove G5 is formed by etching or patterning the second photovoltaic layer 410, the interlayer 310, and the first photovoltaic layer 210 by irradiating laser. The fifth separation groove G5 is substantially identical in structure to that described with reference to FIG. 4D, but may be different in width. The fifth separation groove G5 may be about 40 μm to about 80 μm wide.

In one exemplary embodiment, for example, the fifth separation groove G5 may be formed using the second harmonic of the Nd:YAG laser having a wavelength of about 532 nm and a power of about 0.3 W to about 0.5 W.

Referring to FIG. 6F, the second electrode layer 510 is formed on the second photovoltaic layer 410 and in the fifth separation groove G5. Structure, material, thickness and forming method of the second electrode layer 510 may be substantially identical to those described with reference to FIG. 4E.

Referring to FIG. 6G, the eleventh separation groove G11 and a surrounding separation groove I are formed by irradiating a laser. The eleventh separation groove G11 is narrower than the tenth separation groove G10. The eleventh separation groove G11 is formed from the point or portion of the substantially circular arc or curved arc of the first electrode layer 110 in the ninth separation groove G9, and from the circular arc or curved arc in the tenth separation groove G10, and extending through the second electrode layer 510 and the second photovoltaic layer 410 in the ninth groove G9. As portions of the second photovoltaic layer 410 filling the tenth separation groove G10 are removed, the eleventh separation groove G11 is formed extending through the second electrode layer 510 such that portions of the second photovoltaic layer 410 may remain on both sidewalls of the interlayer 310 and the first photovoltaic layer 210. The eleventh separation groove G11 may be formed using the second harmonic of the Nd:YAG laser having a wavelength of about 532 nm and a power of about 0.3 W to about 0.6 W. The eleventh separation groove G11 may be about 25 μm to about 35 μm wide, which is less than the width of the tenth separation groove G10.

The surrounding separation groove I is formed by irradiating a laser having a wavelength of about 532 nm with a power of about 0.4 W to about 0.7 W.

According to the illustrated embodiment of the invention, the second separation groove G2 is formed in the first electrode layer 110, the first photovoltaic layer 210 is filled therein, and thereafter, the third separation groove G3 is formed such that portions of the first photovoltaic layer 210 may remain to be attached to both sidewalls of the first electrode layer 110 in the second separation groove G2, thereby preventing the possible contamination by residues, which may occur when conductive materials of the first electrode layer 110 undergo sublimation or vaporization during its laser etching. In addition, portions of the first electrode layer 110 are further removed when the ninth separation groove G9 is formed, making it possible to reduce the amount of conductive materials of the first electrode layer 110, which undergo sublimation when the tenth separation groove G10 is formed inside the ninth separate groove G9. Furthermore, the eleventh separation groove G11 is formed such that portions of the second photovoltaic layer 410 may cover both sidewalls of the interlayer 310 located inside the tenth separation groove G10, thereby preventing conductive materials of the interlayer 310 from being sublimated or vaporized. Therefore, the current leakage which may occur due to the electrical connection between the first electrode layer 110 and the interlayer 310 and the electrical connection between the interlayer 310 and the second electrode layer 510, caused by the sublimation of the conductive materials, may be reduced.

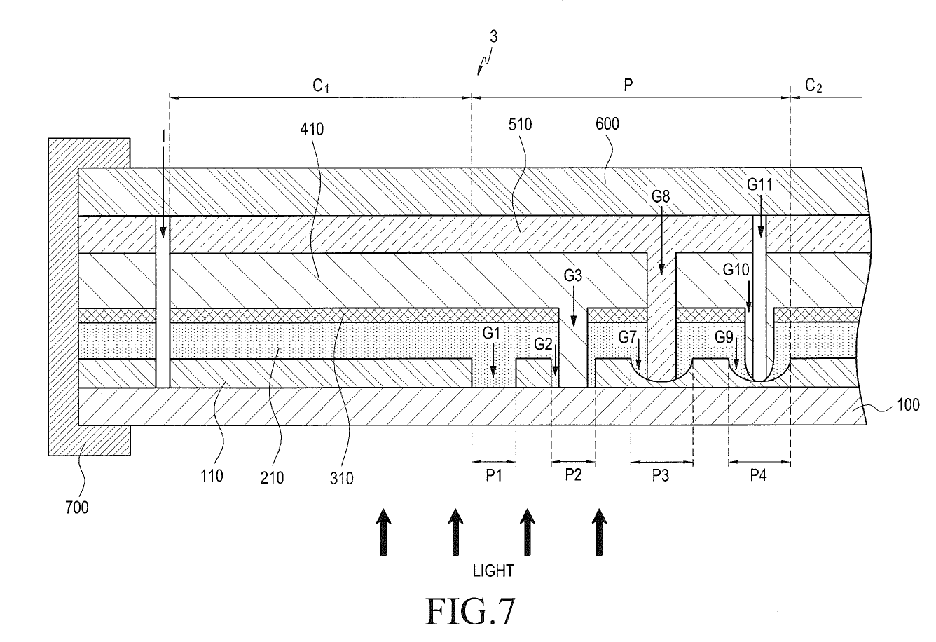

A plan view of a photovoltaic module 3 according to the invention is substantially similar to that shown in FIG. 2. FIG. 7 illustrates an enlarged cross section of another exemplary embodiment of a photovoltaic cell taken along line III-III′ of FIG. 2 according to the invention. In the photovoltaic module 3 according to the illustrated embodiment, first, second and fourth separation regions P1, P2, and P4 except for the third separation region P3 are substantially identical in structure to the first, second and fourth separation regions P1, P2, and P4 described with reference to FIG. 5, so description thereof will be omitted to avoid duplicate description, and only a structure related to the third separation region P3 will be described below.

Referring to FIG. 7, the third separation region P3 has seventh and eighth separation grooves G7 and G8. The seventh separation groove G7 has a bottom which is a concave upper surface of a first electrode layer 110. The bottom of the seventh separation groove G7 has a substantially curved shape like a circular arc in the third separation region P3.

In an exemplary embodiment, the eighth separation groove G8 is formed by laser-etching the first photovoltaic layer 210 filled in the seventh separation groove G7, an interlayer 310 thereon, and the second photovoltaic layer 410 on the interlayer 310. The eighth separation groove G8 is narrower than the seventh separation groove G7, and the bottom has a shape of a substantially circular arc which contacts a circular arc of the seventh separation groove G7. Portions of the first electrode layer 110 remain on the bottoms of the seventh and eighth separation grooves G7 and G8.

A second electrode layer 510 extends from the circular arc of the remaining first electrode layer 110, and fills the eighth separation groove G8, thereby electrically cascade-connecting adjacent solar cells C1 and C2. A thickness of the remaining first electrode layer 110 may be determined taking into account the conductivity of the first electrode layer 110 for an electrical connection between the adjacent solar cells C1 and C2. In one exemplary embodiment, for example, the thickness may be about 2000 Å to about 8000 Å. As similarly described above, as portions of the first electrode layer 110 are removed in advance during forming of the seventh separation groove G7, the sublimation or vaporization of conductive materials of the first electrode layer 110 may be reduced when the eighth separation groove G8 is subsequently formed, contributing to a reduction in conductive residues of the first electrode layer 110, which may be attached onto sidewalls of the eighth separation grooves G8. Therefore, a lifting-off phenomenon which may be caused by conductive residues attached onto sidewalls of the eighth separation groove G8 and in which portions of the second electrode layer 510 filling the eighth separation groove G8 are lifted off, may be reduced.

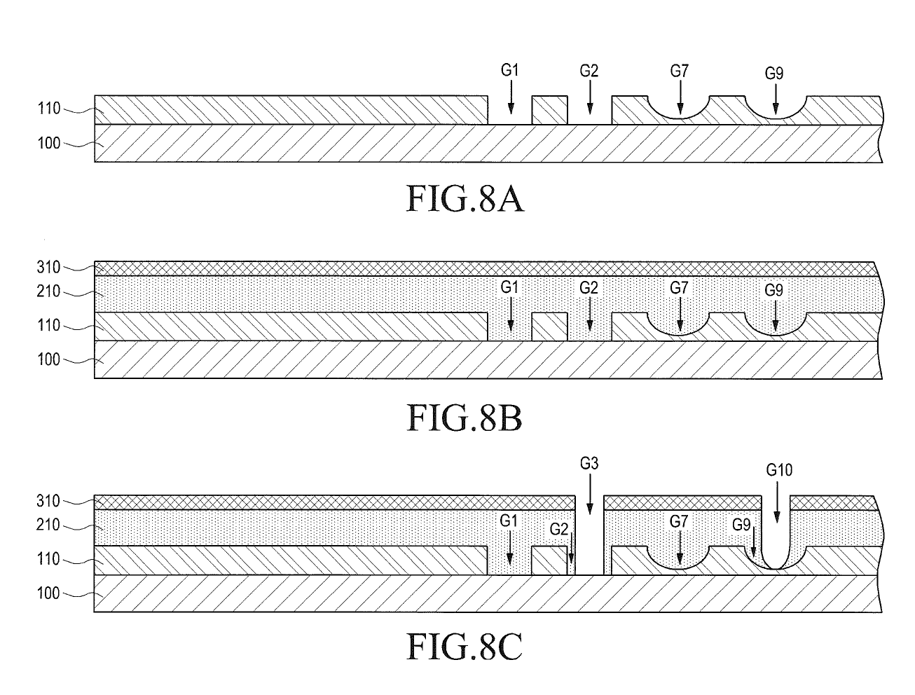

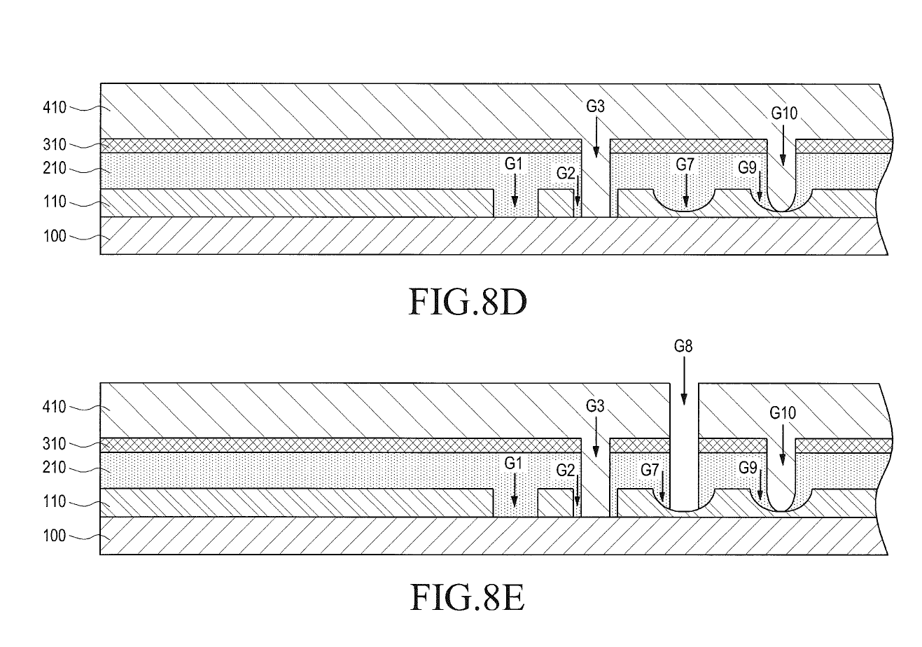

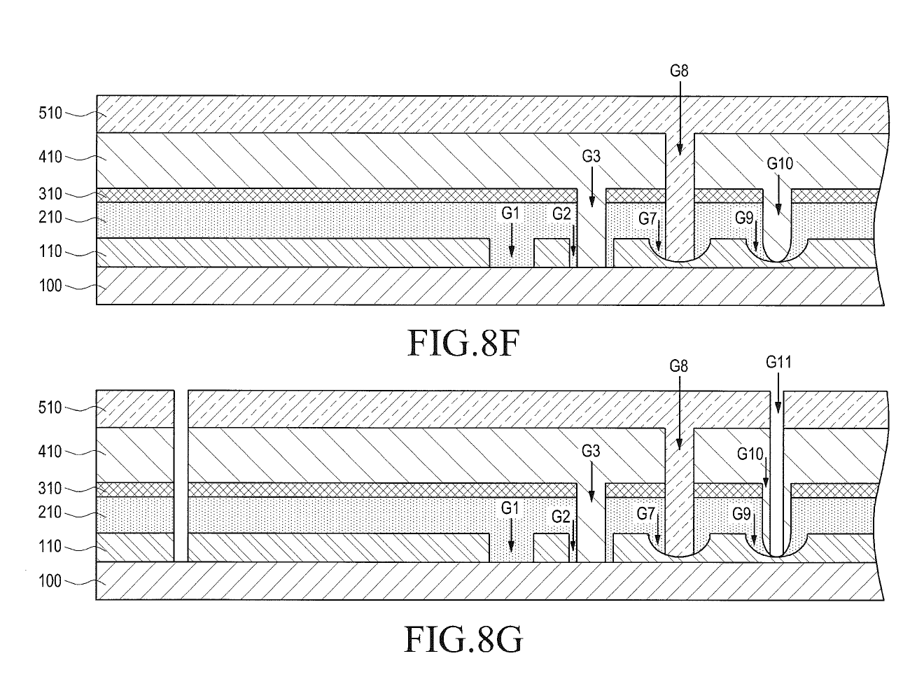

An exemplary embodiment of method of manufacturing the photovoltaic module 3 shown in FIG. 7 will be described below with reference to FIGS. 8A to 8G.

FIGS. 8A to 8G schematically illustrate an exemplary embodiment of a method of manufacturing the photovoltaic module 3 shown in FIG. 7.

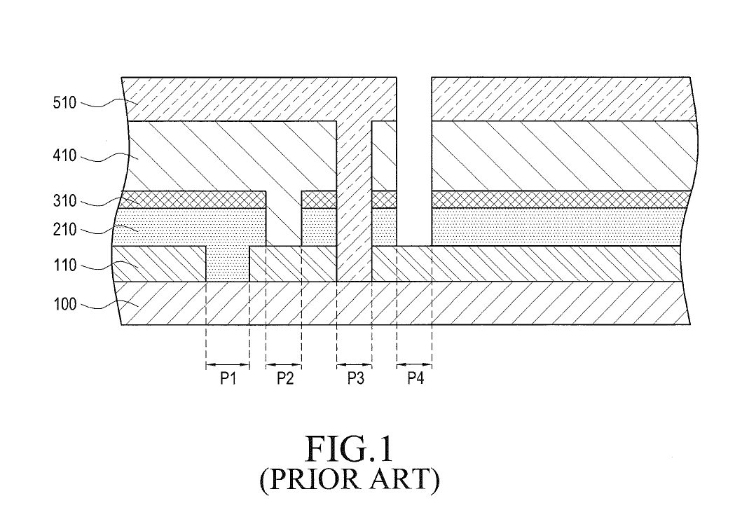

Referring to FIG. 8A, the first electrode layer 110 is formed on the substrate 100. Material, thickness and forming method of the first electrode layer 110 may be substantially similar to those described with reference to FIG. 6A. By patterning the first electrode layer 110 by irradiating laser thereto, the first, second, seventh and ninth separation grooves G1, G2, G7, and G9 are formed in the locations corresponding to the first, second, third and fourth separation regions P1, P2, P3, and P4 in FIG. 1. In one exemplary embodiment, for example, the first and second separation grooves G1 and G2 may be formed by irradiating the Nd:YAG laser having a wavelength of about 1064 nm and a power of about 10 W to about 16 W, onto the first electrode layer 110. The first and second separation grooves G1 and G2 may be about 40 μm to about 80 μm wide. The seventh and ninth separation grooves G7 and G9 may be formed by irradiating the Nd:YAG laser having a wavelength of about 1064 nm and a power of about 2 W to about 5 W, onto the first electrode layer 110. The seventh and ninth separation grooves G7 and G9 may be about 40 μm to 80 μm wide. By adjusting intensity of laser to have Gaussian distribution, such as by adjusting a slit device of a laser generating device, the bottoms of the seventh and ninth separation grooves G7 and G9 may be shaped to have a curved shape like a substantially circular arc as shown in FIG. 8A. The first electrode layer 110 remaining between the substrate 100 and the bottoms of the seventh and ninth separation grooves G7 and G9 may be about 2000 Å to about 8000 Å thick taken perpendicular to the substrate 100.

Referring to FIG. 8B, on the first electrode layer 110 is formed the first photovoltaic layer 210, filling the first, second, seventh, and ninth separation grooves G1, G2, G7, and G9. The first photovoltaic layer 210 is filled in the first and second separation grooves G1 and G2 from the front surface of the substrate 100, but it is filled in the seventh and ninth separation grooves G7 and G9 from the surfaces of the circular arc or curved arc of the partially remaining first electrode layer 110. Material, thickness and forming method of the first photovoltaic layer 210 may be substantially identical to those described in FIG. 6B.

On the first photovoltaic layer 210 is formed the interlayer 310, whose material, thickness and forming method may be substantially identical to those described in FIG. 6B.

Referring to FIG. 8C, the third and tenth separation grooves G3 and G10 may be formed by etching or patterning the first photovoltaic layer 210 and the interlayer 310 by irradiating a laser thereto. The third and tenth separation grooves G3 and G10 may be formed by the method of manufacturing the third and tenth separation groove G3 and G10, respectively, described with reference to FIG. 6C.

Referring to FIG. 8D, the second photovoltaic layer 410 is formed on the interlayer 310, filling the third and tenth separation grooves G3 and G10. Material, thickness and forming method of the second photovoltaic layer 410 may be substantially identical to those described with reference to FIG. 6D.

Referring to FIG. 8E, the eighth separation groove G8 is formed by etching or patterning the second photovoltaic layer 410, the interlayer 310, and the first photovoltaic layer 210 by irradiating laser. The eighth separation groove G8 is formed from the surface of the circular arc or curved arc of the first electrode layer 110, is located inside the seventh separation groove G7, and extends through the second photovoltaic layer 410, the interlayer 310, and the first photovoltaic layer 210. The eighth separation groove G8 is narrower than the seventh separation groove G7, and its bottom has a shape of a substantially circular arc which contacts the circular arc or curved arc of the seventh separation groove G7.

In one exemplary embodiment, for example, the eighth separation groove G8 having a width of about 25 μm to about 35 μm may be formed using the second harmonic of the Nd:YAG laser having a wavelength of about 532 nm and a power of about 0.3 W to about 0.5 W.

Referring to FIG. 8F, the second electrode layer 510 is formed on the second photovoltaic layer 410 and in the eighth separation groove G8. The second electrode layer 510 is formed from the surface of the circular arc or curved arc of the first electrode layer 110 in an adjacent solar cell, filling the eighth separation groove G8, thereby electrically cascade-connecting adjacent solar cells C1 and C2. Because portions of the first electrode layer 110 on the bottom of the eighth separation groove G8 were removed in advance when the seventh separation groove G7 was formed, the amount of sublimated or vaporized conductive materials of the first electrode layer 110 may be reduced when the eighth separation groove G8 is formed. Therefore, the conductive residues attached onto the sidewalls of the eighth separation groove G8 may be minimized, reducing the lifting-off phenomenon in which the second electrode layer 510 filling the eighth separation groove G8 is partially lifted off. Material, thickness and forming method of the second electrode layer 510 may be substantially identical to those described with reference to FIG. 6F.

Referring to FIG. 8G, the eleventh separation groove G11 and a surrounding separation groove I are formed by irradiating a laser. The eleventh separation groove G11 may be substantially identical in structure and manufacturing method to the eleventh separation groove G11 described with reference to FIG. 6G. The surrounding separation groove I is formed using the second harmonic of the Nd:YAG laser having a wavelength of about 532 nm and a power of about 0.4 W to about 0.7 W.

According to the illustrated embodiment of the invention, the second separation groove G2 is formed in the first electrode layer 110, the first photovoltaic layer 210 is filled therein, and thereafter, the third separation groove G3 is formed such that portions of the first photovoltaic layer 210 may remain on both sidewalls of the first electrode layer 110 in the second separation groove G2, thereby avoiding the possible current leakage which may occur when sublimated or vaporized residues of conductive materials of the first electrode layer 110 are electrically leakably connected to the interlayer 310 during laser etching to form the third separation groove G3.

In addition, because portions of the first electrode layer 110 located on the bottom of the eighth separation groove G8 are further removed in advance during forming of the seventh separation groove G7, the amount of sublimated or vaporized conductive materials of the first electrode layer 110 may be reduced when the eighth separation groove G8 is formed, thereby reducing the lifting-off phenomenon in which the second electrode layer 510 filling the eighth separation groove G8 is partially lifted off from the eighth separation groove G8 because of the residues of the conductive materials, attached onto sidewalls the eighth separation groove G8.

Moreover, because portions of the first electrode layer 110 are removed in advance when the ninth separation groove G9 is formed, the amount of sublimated or vaporized conductive materials of the first electrode layer 110 may be reduced when the tenth separation groove G10 is formed inside the ninth separation groove G9, thereby reducing the possible current leakage path which may occur when the first electrode layer 110 and the interlayer 310 are electrically leakably connected.

Besides, the eleventh separation groove G11 is formed such that portions of the second photovoltaic layer 410 may cover both sidewalls of the interlayer 310, located inside the tenth separation groove G10, thereby preventing sublimation or vaporization of conductive materials of the interlayer 310. Therefore, the leakage current may be reduced, which may occur due to the electrical connection between the first electrode layer 110 and the interlayer 310, and the electrical connection between the interlayer 310 and the second electrode layer 510.

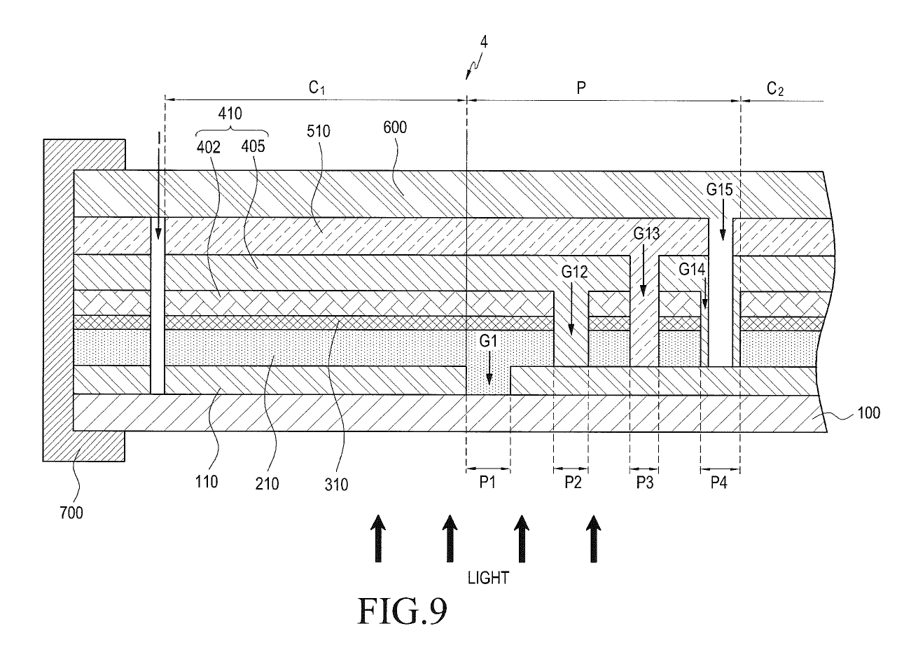

A plan view of a photovoltaic module 4 according to the invention is substantially similar to that shown in FIG. 2. FIG. 9 is an enlarged cross section of another exemplary embodiment of a photovoltaic cell taken along line III-III′ of FIG. 2 according to the invention. The same drawing reference numerals will be understood to refer to the same elements, features and structures, and the duplicate description will be omitted for convenience.

Referring to FIG. 9, the substrate 100 is the base of solar cells, and commonly the substrate 100 may include an insulating glass or a flexible plastic.

The substrate 100 includes front and rear surfaces, and on the front surface is the first electrode layer 110. The first electrode layer 110 may include a transparent and conductive material because the solar light is incident on the solar cells through the first electrode layer 110, which serves to flow charges generated in the solar cells.

In the first electrode layer 110 is the first separation groove G1 of the first separation region P1. The first electrode layer 110 is electrically separated between adjacent solar cells C1 and C2 by the first separation groove G1.

The first photovoltaic layer 210 is on the first electrode layer 110, and generates electron-hole pairs by absorbing the solar light.

The first photovoltaic layer 210 is on the surface of the first electrode layer 110, filling the first separation groove G1 in the first electrode layer 110. On the first photovoltaic layer 210 is the interlayer 310. The second photovoltaic layer 410 is on the interlayer 310. The second photovoltaic layer includes a first layer 402 directly on the interlayer 310. The first layer 402 may be about 500 Å to about 2500 Å thick.

Twelfth and fourteenth separation grooves G12 and 14 are extended from the top of the first electrode layer 110, extending through the first layer 402, the interlayer 310, and the first photovoltaic layer 210. The twelfth separation groove G12 corresponds to the second separation region P2, and the fourteenth separation groove G14 corresponds to the fourth separation region P4.

A second layer 405, which is a remainder of the second photovoltaic layer 410, is directly on the first layer 402 and fills the twelfth separation groove G12, and covers both opposing sidewalls of the first layer 402, the interlayer 310, and the first photovoltaic layer 210 in the fourteenth separation groove G14. The second layer 405 may be about 1.5 μm to about 2.0 μm thick. The second layer 405 covers both opposing sidewalls of the interlayer 310 in the twelfth and fourteenth separation grooves G12 and G14, thereby reducing current leakage which may occur when a second electrode layer 510 and the interlayer 310 are electrically leakably connected.

The second photovoltaic layer 410 including the first and second layers 402 and 405 generates electron-hole pairs by absorbing the solar light.

A thirteenth separation groove G13 extends from the surface of the first electrode layer 110, and through the second photovoltaic layer 410 including the first and second layers 402 and 405, the interlayer 310, and the first photovoltaic layer 210. The thirteenth separation groove G13 corresponds to the third separation region P3.

The second electrode layer 510 is on the second layer 405, filling the thirteenth separation groove G13. The second electrode layer 510 may be from the surface of the first electrode layer 110, and filling the thirteenth separation groove G13. Therefore, the second electrode layer 510 of the first solar cell C1 and the first electrode layer 110 of the adjacent second cell C2 are electrically cascade-connected through the thirteenth separation groove G13.

A fifteenth separation groove G15 extends from the surface of the first electrode layer 110, and through the second electrode layer 510 and the second layer 405. The fifteenth separation groove G15 is located inside the fourteenth separation groove G14 and corresponds to the fourth separation region P4, and is narrower than the fourteenth separation groove G14. The fifteenth separation groove G15 electrically separates the second electrode layer 510 in between the adjacent first and second solar cells C1 and C2. In an exemplary embodiment, the fifteenth separation groove G15 is formed such that the second layer 405 may cover both opposing sidewalls of the first layer 402, the interlayer 310 and the first photovoltaic layer 210 located in the fourteenth separation groove G14, thereby preventing conductive materials of the interlayer 310 from being sublimated or vaporized during laser etching to form the fifteenth separation groove G15. Thus, the current leakage which may occur when the sublimated or vaporized conductive materials of the interlayer 310 are electrically leakably connected to the second electrode layer 510 or the first electrode layer 110, may be reduced.

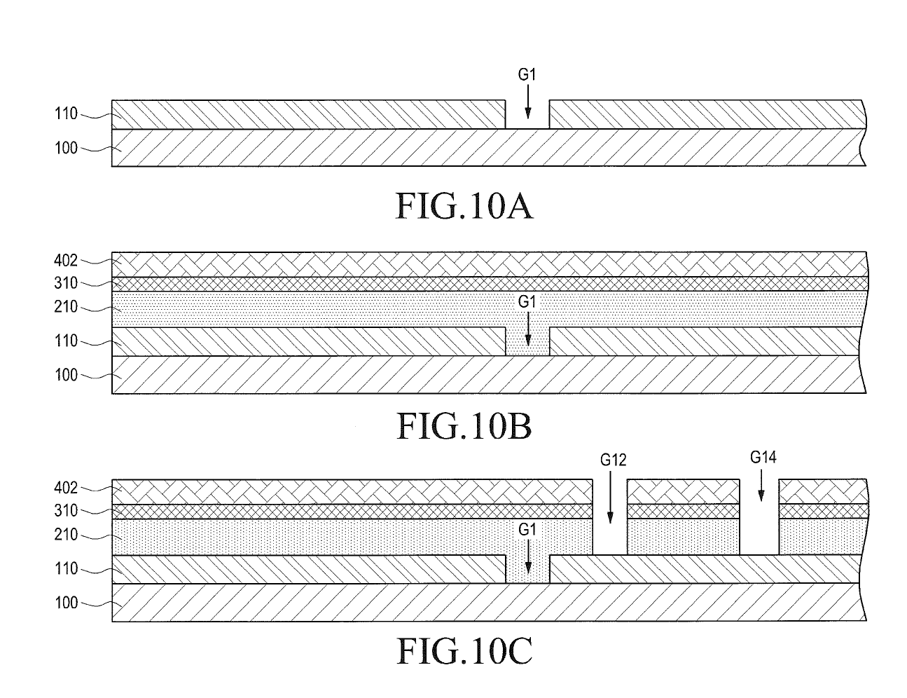

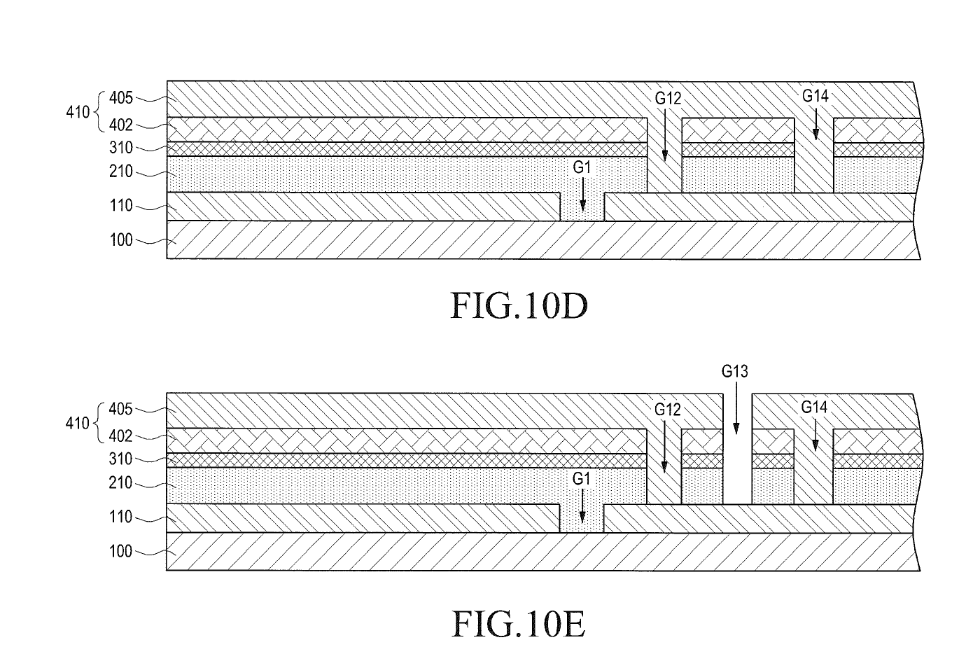

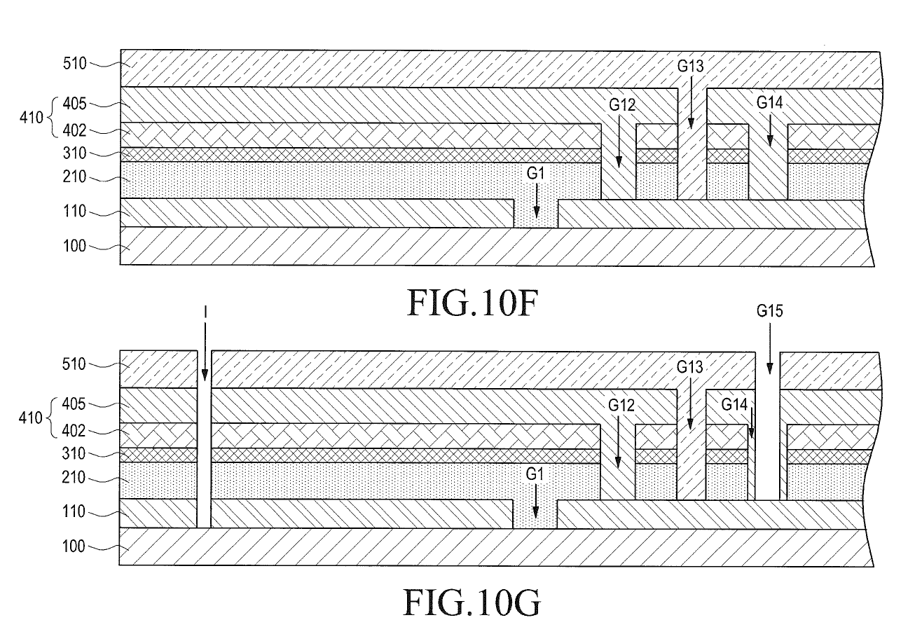

An exemplary embodiment of a method of manufacturing the photovoltaic module 4 shown in FIG. 9 will be described in detail below with reference to FIGS. 10A to 10G.

FIGS. 10A to 10G schematically illustrate an exemplary embodiment of a method of manufacturing the photovoltaic module 4 shown in FIG. 9.

Referring to FIG. 10A, the first electrode layer 110 is formed on a substrate 100 by CVD or sputtering. Material, thickness and forming method of the first electrode layer 110 may be substantially identical to those described in the foregoing embodiments. The first electrode layer 110 may be formed to have a thickness of about 1.0 μm to about 2.0 μm. A first separation groove G1 is formed in the location corresponding to the first separation region P1 in FIG. 9 by patterning the first electrode layer 110 such as by irradiating a laser onto the first electrode layer 110, or onto a rear surface of the substrate 100 on which the first electrode layer 110 is formed. In one exemplary embodiment, for example, the first separation groove G1 may be formed by etching the first electrode layer 110 using the Nd:YAG laser having a wavelength of about 355 nm and a power of about 3 W to about 6 W. The first separation groove G1 may be about 20 μm to about 190 μm wide.

Referring to FIG. 10B, the first photovoltaic layer 210 is formed on the first electrode layer 110 from the top of the substrate 100 by CVD, filling the first separation groove G1. Material, thickness and manufacturing method of the first photovoltaic layer 210 may be substantially identical to those described in the forgoing embodiments.

The interlayer 310 is formed on the first photovoltaic layer 210. The interlayer 310 may include zinc oxide (ZnO) or phosphorus-doped silicon oxide (SiOx). When including zinc oxide (ZnO), the interlayer 310 may be formed by CVD to have a thickness of about 200 Å to about 1000 Å.

As described with reference to FIG. 9, the first layer 402 which is a portion of the second photovoltaic layer 410, is formed directly on the interlayer 310. In one exemplary embodiment, for example, the first layer 402 may be formed about 500 Å to about 2500 Å thick by CVD.

Referring to FIG. 10C, twelfth and fourteenth separation grooves G12 and G14 are formed from the surface of the first electrode layer 110 by etching or patterning the first layer 402, the interlayer 310 and the first photovoltaic layer 210 by irradiating a laser thereto. The twelfth separation groove G12 is formed to correspond to the second separation region P2 shown in FIG. 9, and the fourteenth separation groove G14 is formed to correspond to the fourth separation region P4 in FIG. 9. The twelfth separation groove G12 may be about 50 to 100 μm wide, and the fourteenth separation groove G14 may be about 60 μm to about 200 μm wide. The twelfth and fourteenth separation grooves G12 and G14 may be formed using the Nd:YAG laser having a wavelength of about 532 nm and a power of about 0.4 W or below.

Referring to FIG. 10D, the second layer 405 which is a remaining portion of the second photovoltaic layer 410, is formed directly on the first layer 402 by CVD, filling the twelfth and fourteenth separation grooves G12 and G14. The 5 second layer 405 may be about 1.5 μm to about 2.0 μm thick.

The second photovoltaic layer 410 including the first and second layers 402 and 405 may include, for example, microcrystalline silicon (mc-Si) or polycrystalline silicon (p-Si). Although not illustrated, the second photovoltaic layer 410 may have a structure in which a p-type mc-Si layer, an intrinsic mc-Si layer, and an n-type mc-Si layer are sequentially stacked on the interlayer 310.

Referring to FIG. 10E, the thirteenth separation groove G13 is formed from the surface of the first electrode layer 110, and extends through the second photovoltaic layer 410 including the first and second layers 402 and 405, the interlayer 310, and the first photovoltaic layer 210. The thirteenth separation groove G13 is formed to correspond to the third separation region P3 in FIG. 9. The thirteenth separation groove G13 may be about 50 μm to about 100 μm wide, and may be formed using the second harmonic of the Nd:YAG laser having a wavelength of about 532 nm and a power of about 0.4 W.

Referring to FIG. 10F, the second electrode layer 510 is formed directly on the second layer 405 from the surface of the first electrode layer 110, filling the thirteenth separation groove G13. Material, thickness and manufacturing method of the second electrode layer 510 may be substantially identical to those described in the foregoing embodiments.

Referring to FIG. 10G, the fifteenth separation groove G15 and the surrounding separation groove I are formed by irradiating a laser. The fifteenth separation groove G15 is formed from the surface of the first electrode layer 110, and extends through the second electrode layer 510 and the second layer 405 filling the fourteenth separation groove G13. The fifteenth separation groove G15 is formed such that a portion of the second layer 405 filled in the fourteenth separation groove G14 is partially removed and portions of the second layer 405 may remain on both opposing sidewalls of the first layer 402, the interlayer 310 and the first photovoltaic layer 210. The fifteenth separation groove G15 may be formed using the second harmonic of the Nd:YAG laser having a wavelength of about 532 nm and a power of about 0.4 W. The fifteenth separation groove G15 may be 40 μm to about 180 μm wide, which is less than the width of the fourteenth separation groove G14.

The surrounding separation groove I may be formed by irradiating the second harmonic of the Nd:YAG laser having a wavelength of about 532 nm and a power of about 0.3 W to about 0.7 W. The surrounding separation groove I extends along edges of the photovoltaic module 4 in horizontal and vertical directions as illustrated in FIG. 2, and is formed from the surface of the substrate 100, and extends through the second electrode layer 510, the second photovoltaic layer 410, the interlayer 310, the first photovoltaic layer 210, and the first electrode layer 110.

As described above, when the thirteenth separation groove G13 is formed by performing laser etching or patterning after the second layer 405 is formed, the second harmonic of the Nd:YAG laser having a wavelength of about 532 nm is used with a power of about 0.4 W, whereas when the twelfth and fourteenth separation grooves G12 and G14 are formed by performing laser etching or patterning after the first layer 402 is formed, the second harmonic of the Nd:YAG laser having a wavelength of about 532 nm may be used with a power of about 0.2 W to about 0.4 W. In other words, when only the first layer 402 which is a portion of the second photovoltaic layer 410 is formed, laser etching or patterning may be performed using lower laser power compared with when the entire layer of the second photovoltaic layer 410 is formed. The use of the lower laser power may contribute to a decrease in sublimation or vaporization of conductive materials of the first electrode layer 110, thereby reducing the current leakage which may occur when the interlayer 310 and conductive materials of the first electrode layer 110 are electrically leakably connected due to the sublimation or vaporization of the conductive materials of the first electrode layer 110. The power may be changed according to the type of the laser used.

As is apparent from the foregoing description, according to exemplary embodiments of the invention, the leakage current of the solar cells may be reduced, preventing degradation in efficiency of the solar cells and reducing lifting off of plug materials.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A photovoltaic module comprising:
a plurality of solar cells; and
a plurality of solar cell separation regions which separates adjacent solar cells;
each of the solar cells comprising;
a first electrode layer on a transparent substrate and electrically separated from the first electrode layer of an adjacent solar cell,
a second electrode layer on the first electrode layer and electrically separated from the second electrode layer of the adjacent solar cell,
a first electrical and optical photovoltaic layer and a second electrical and optical photovoltaic layer between the first and second electrode layers, and
a conductive interlayer between the first and second photovoltaic layers; and
at least one of the solar cell separation regions comprising:
a first separation groove which extends completely through a thickness of the first electrode layer and which the first photovoltaic layer fills, and
a second separation groove which extends completely through thicknesses of the first photovoltaic layer which fills the first separation groove, and the interlayer.

2. The photovoltaic module of claim 1, wherein the second photovoltaic layer fills the second separation groove.

3. The photovoltaic module of claim 2, wherein portions of the first photovoltaic layer are between sidewalls of the first electrode layer of the first separation groove and sidewalls of the second photovoltaic layer in the second separation groove.

4. The photovoltaic module of claim 3, wherein the at least one of the solar cell separation regions further comprises:
a third separation groove which electrically separates the second electrode layer from the second electrode layer of the adjacent solar cell; and
a fourth separation groove which has a width greater than a width of the third separation groove, wherein the fourth separation groove separates the first photovoltaic layer and the interlayer from the first photovoltaic layer and the interlayer of the adjacent solar cell.

5. The photovoltaic module of claim 4, wherein portions of the second photovoltaic layer are between sidewalls of the third separation groove and sidewalls of the fourth separation groove.

6. The photovoltaic module of claim 5, wherein
the first electrode layer includes a first concave surface in the upper surface thereof, and
the fourth separation groove includes a bottom in a shape of a substantially circular arc which is on the first concave surface of the first electrode layer.

7. The photovoltaic module of claim 6, wherein the third separation groove includes a bottom in a shape of a substantially circular arc which contacts the circular arc of the bottom of the fourth separation groove at least one point or portion.

8. The photovoltaic module of claim 7, wherein
the first electrode layer further includes a second concave surface in the upper surface thereof; and
the at least one of the solar cell separation regions further comprises”
a conductive plug which electrically connects the first and second electrode layers of the adjacent solar cells, and
a bottom of the conductive plug contacts the second concave surface of the first electrode layer.

9. A photovoltaic module comprising:
a plurality of solar cells; and
a plurality of solar cell separation regions which separates first and second solar cells adjacent to each other;
each of the solar cells comprising;
a first electrode layer on a transparent substrate,
a second electrode layer over the first electrode layer,
a first photovoltaic layer and a second photovoltaic layer between the first and second electrode layers, and
an electrically conductive interlayer between the first and second photovoltaic layers; and
at least one of the solar cell separation regions comprising:
a first separation groove which separates the first electrode layer of the first solar cell from the first electrode layer of the second solar cell,
a second separation groove which separates the second electrode layer of the first solar cell from the second electrode layer of the second solar cell,
a conductive plug which electrically connects the separated second electrode layer of the first solar cell to the separated first electrode layer of the adjacent second solar cell, and
a third separation groove which has a width greater than that of the second separation groove;
wherein in the at least one of the solar cell separation regions,
the second photovoltaic layer over the separated first electrode layer is separated by the second separation groove;
the first photovoltaic layer and the interlayer over the separated first electrode layer are separated by the third separation groove; and
portions of the separated second photovoltaic layer are between sidewalls of the third separation grooves and sidewalls of the second separation groove.

10. The photovoltaic module of claim 9, wherein
the first electrode layer includes a first concave surface in the upper surface thereof, and
the third separation groove includes a bottom in a shape of a substantially circular arc which is situated on the first concave surface of the first electrode layer.

11. The photovoltaic module of claim 10, wherein the second separation groove includes a bottom in a shape of a substantially circular arc which contacts the circular arc of the third separation groove at least one point or portion.

12. The photovoltaic module of claim 11, wherein
the first electrode layer includes a second concave surface in the upper surface thereof; and
the conductive plug includes a bottom which contacts the concave surface of the separated first electrode layer.

13. A photovoltaic module comprising:
a plurality of solar cells, adjacent cells of which are electrically cascade-connected; and
a plurality of solar cell separation regions which separate the adjacent solar cells;
each of the solar cells comprising;
a first electrode layer on a transparent substrate,
a first photovoltaic layer on the first electrode layer,
a conductive interlayer on the first photovoltaic layer,
a second photovoltaic layer including first and second layers, on the conductive interlayer, and
a second electrode layer on the second layer;
wherein at least one of the solar cell separation regions comprises a first separation groove which extends from a surface of the first electrode layer, and through the first layer of the second photovoltaic layer, the interlayer, and the first photovoltaic layer.

14. The photovoltaic module of claim 13, wherein the second layer of the second photovoltaic layer fills the first separation groove.

15. The photovoltaic module of claim 14, wherein the at least one of the solar cell separation regions further comprises:
a second separation groove which separates the second electrode layer from the second electrode layer of an adjacent solar cell;
a third separation groove which has a width greater than a width of the second separation groove, wherein the third separation groove extends through the first photovoltaic layer, the interlayer, and the first layer of the second photovoltaic layer; and
portions of the second layer of the second photovoltaic layer are between sidewalls of the second separation groove and sidewalls of the third separation groove.

16. The photovoltaic module of claim 15, wherein the at least one of the solar cell separation regions further comprises a fourth separation groove between the first and second separation grooves, wherein the fourth separation groove extends through the second photovoltaic layer, the interlayer, and the first photovoltaic layer.

17. A method for separating solar cells, the method comprising:
forming a first electrode layer on a transparent layer;
forming first and second separation grooves which separate the first electrode layer;
forming a first photovoltaic layer on the first electrode layer, the first photovoltaic layer filling the first and second separation grooves;
forming a conductive interlayer on the first photovoltaic layer; and
forming a third separation groove which separates the conductive interlayer and the first photovoltaic layer filled in the second separation groove.

18. The method of claim 17, further comprising forming a fourth separation groove which extends parallel to the third separation groove and through the conductive interlayer and the first photovoltaic layer, such that a portion of the first photovoltaic layer remains on a bottom of the fourth separation groove.

19. The method of claim 18, further comprising:
forming a second photovoltaic layer on the conductive interlayer, the second photovoltaic layer filling the fourth separation groove;
forming a second electrode layer on the second photovoltaic layer; and
forming a fifth separation groove which separates the second photovoltaic layer filling the fourth separation groove, and the second electrode layer.

20. The method of claim 17, further comprising:
forming a fourth separation groove to extend in parallel to the first and second separation grooves and have a concave shape at a bottom of the first electrode layer;
filling the fourth separation groove with the first photovoltaic layer;
forming a fifth separation groove, which separates the first photovoltaic layer filling the fourth separation groove and the conductive interlayer, and includes a bottom in a shape of a substantially circular arc;
forming a second photovoltaic layer on the conductive interlayer, the second photovoltaic layer filling the fifth separation groove;
forming a second electrode layer on the second photovoltaic layer; and
forming a sixth separation groove, which separates the second photovoltaic layer filling the fifth separation groove and the second electrode layer, and includes a bottom in a shape of a substantially circular arc.

21. The method of claim 20, further comprising:
forming a seventh separation groove disposed between the second and fourth separation grooves and having a concave shape on a top of the first electrode;
filling the seventh separation groove with the first photovoltaic layer; and
forming an eighth separation groove, which separates the second photovoltaic layer, the conductive interlayer, and the first photovoltaic layer filling the seventh groove, and includes a bottom in a substantially circular arc.

22. A method for separating solar cells, the method comprising:
forming a first electrode layer on a transparent substrate;
forming a first separation groove which separates the first electrode layer;
forming a first photovoltaic layer which fills the first separation groove, on the first electrode layer;
forming a conductive interlayer on the first photovoltaic layer;
forming a first layer of a second photovoltaic layer, on the conductive interlayer;
forming second and third separation grooves which separate the first photovoltaic layer, the conductive interlayer, and the first layer;
forming a second layer as a remainder of the second photovoltaic layer on the first layer, wherein the second layer fills the second and third separation grooves;
forming a fourth separation groove between the second and third separation grooves, wherein the fourth separation groove separates the second photovoltaic layer including the first and second layers, the conductive interlayer, and the first photovoltaic layer;
forming a second electrode layer which fills the fourth separation groove, on the second layer; and
forming a fifth separation groove that separates the second layer filled in the third separation groove and the second electrode layer.
